(19) United States
(12) Patent Application Publication
(10) Pub. No.: US 2026/0114223 A1
(43) Pub. Date: Apr. 23, 2026

(54) SEMICONDUCTOR CHIP MANAGEMENT APPARATUS, SEMICONDUCTOR CHIP MANAGEMENT METHOD, AND SEMICONDUCTOR CHIP FABRICATION METHOD

(71) Applicant: FUJI ELECTRIC CO., LTD., Kanagawa (JP)

(72) Inventor: Taketo TSUJI, Chiba-city (JP)

(21) Appl. No.: 19/308,265

(22) Filed: Aug. 24, 2025

(30) Foreign Application Priority Data
Oct. 18, 2024 (JP) 2024-184289

(51) Int. Cl. H01L 21/67; G06T 7/00

(52) U.S. Cl. CPC H10P 72/0618; G06T 7/0004; G06T 2207/30148

(57) ABSTRACT

Provided is a semiconductor chip management apparatus including an acquiring unit which acquires an image of a metal portion of a semiconductor chip, an image processing unit which extracts an appearance feature of the metal portion from the image, and a recording unit which records the appearance feature as identification information on the semiconductor chip. The recording unit may record the appearance feature and a fabrication history of the semiconductor chip in association with each other. The semiconductor chip may have a semiconductor substrate, and a protective film provided above an upper surface of the semiconductor substrate and covering at least part of the metal portion, and the acquiring unit may acquire the image of the metal portion covered with the protective film.

The contents of the following patent application(s) are incorporated herein by reference:
NO. 2024-184289 filed in JP on Oct. 18, 2024.

### BACKGROUND

### 1. Technical Field

The present invention relates to a semiconductor chip management apparatus, a semiconductor chip management method, and a semiconductor chip fabrication method.

### 2. Related Art

Patent Document 1 describes “a semiconductor integrated circuit capable of directly writing all individual management information and test information on a chip during a fabrication process into the chip, reading this upon occurrence of failure after an assembly process, and taking this as basic data for failure analysis”. Patent Document 2 describes a method of “verifying image data on a grinding mark in a back surface of a semiconductor wafer, which is imported into an image importing apparatus previously, and image data on a grinding mark in a back surface of an LSI chip with these pieces of data superimposed on each other and specifying an acquiring position on a semiconductor wafer of the LSI chip”. Patent Document 3 describes a method of “verifying image data on a contact mark 12 or the contact mark 12 and a dicing mark 13 and each piece of image data stored in a storage unit 22 and specifying a formation position on a semiconductor wafer of the LSI chip”.
Patent Document 1 Japanese Patent Application Publication No. 2000-228341
Patent Document 2 Japanese Patent Application Publication No. 2004-055882
Patent Document 3 Japanese Patent Application Publication No. 2007-165389

### BRIEF DESCRIPTION OF THE DRAWINGS

FIG. 1 is a conceptual view showing an individual identification method for a semiconductor chip 30 in a comparative example.

FIG. 2 is a conceptual view showing an individual identification method for the semiconductor chip 30 according to the present invention.

FIG. 3 is a diagram showing an example of a management apparatus 100 in an example of the present invention.

FIG. 4 is a view illustrating an image acquiring position of the semiconductor chip 30 in a top view.

FIG. 5 is a view showing an example of an E-E′ cross section of FIG. 4.

FIG. 6 is an enlarged view of a region A of FIG. 4.

FIG. 7 is a view showing an example of a C-C′ cross section of FIG. 6.

FIG. 8 is an enlarged view of a region B of FIG. 4.

FIG. 9 is a view showing an example of a D-D′ cross section of FIG. 8.

FIG. 10 is a chart showing an example of a fabrication flow of the semiconductor chip 30 to which the management method of the present invention was adopted.

FIG. 11 is a chart showing an example of a verification flow for the semiconductor chip 30.

### DESCRIPTION OF EXEMPLARY EMBODIMENTS

Hereinafter, the present invention will be described through embodiments of the invention, but the following embodiments do not limit the invention according to claims. Also, not all of combinations of features described in the embodiments are essential to the solving means of the invention.

In the present specification, a case where a term such as “same” or “equal” is mentioned may include a case where an error due to a variation in fabrication or the like is included. The error is, for example, within 10%.

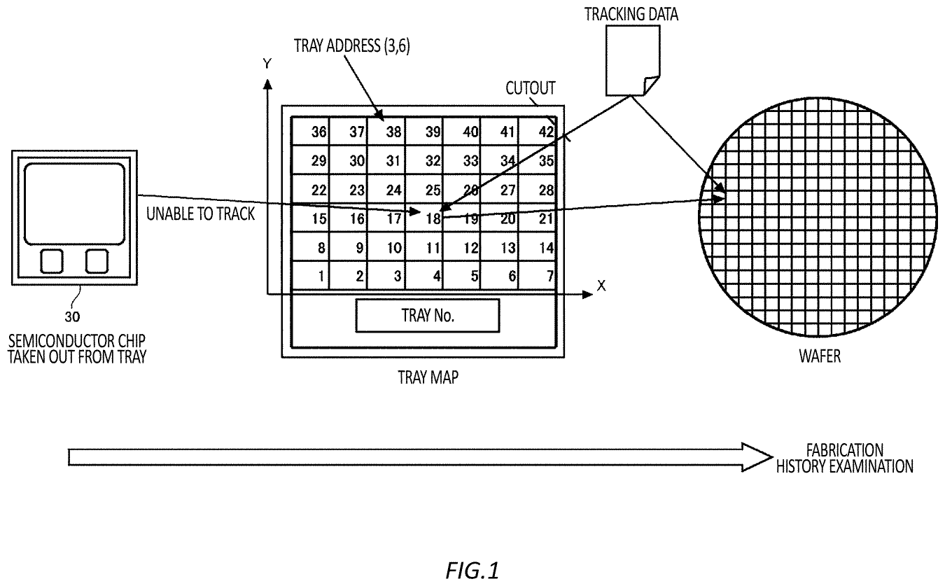

FIG. 1 is a conceptual view showing an individual identification method for a semiconductor chip 30 in a comparative example. In fabrication of a semiconductor apparatus, many semiconductor devices formed on one semiconductor wafer are formed into chips in a dicing process, and these are picked up and housed in a tray. A unique chip ID including a lot No. and a wafer No. of a wafer formed, and XY coordinates in the wafer is given to each semiconductor chip 30. The chip ID is linked to a tray No. and a tray address of the chip housed. The tray address of the present example is represented by the XY coordinates. These pieces of tracking data are electromagnetically recorded as a tracking data file.

In the present example, individual identification of the semiconductor chip 30 is performed with the tray No. and the tray address where the chip is housed. A cutout for deciding orientations of an X axis and a Y axis at the tray address may be provided. The chip ID is specified from the tray No. and the tray address, and from the chip ID, a fabrication history can be examined with reference back to the lot No. and the wafer No. of the wafer, the XY coordinates in the wafer, and the like.

However, in the present example, it is difficult to individually identify the semiconductor chip 30 after the semiconductor chip 30 is taken out from the tray. Thus, after the semiconductor chip 30 is taken out from the tray, it is difficult to track the fabrication history of the chip and the like. In order to make it possible to track the fabrication history of each chip and the like even after the semiconductor chip 30 is taken out from the tray, for example, there is a method of punching an individual identification No. in the semiconductor chip 30 by laser engraving or ink marking (see Patent Document 1), but it is not practical due to dirt, dust, or the like upon punching. Other than above, tracking methods by verification with a grinding mark in a wafer back surface (see Patent Document 2) and by verification with a dicing mark or a probe mark (see Patent Document 3) have been proposed, but there is a problem that tracking in analysis of a determination accuracy or disruption after packaging is difficult.

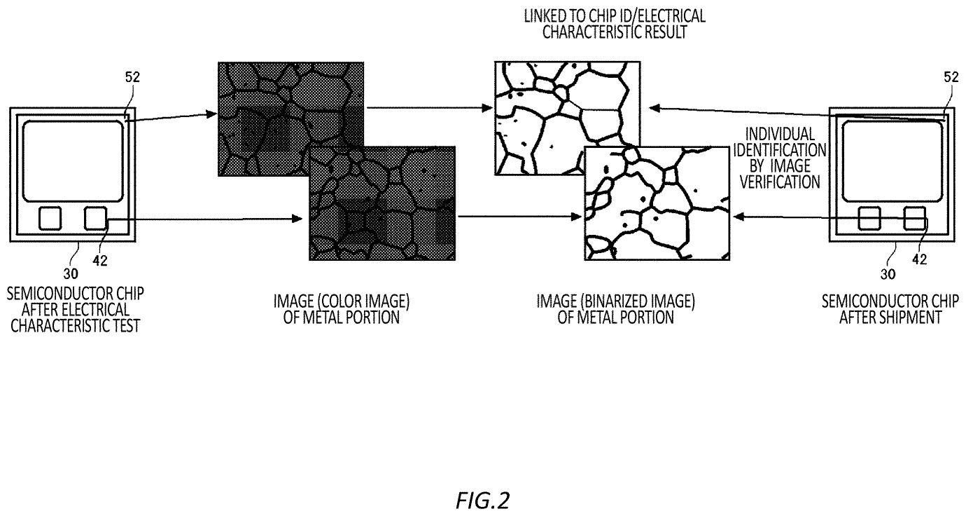

FIG. 2 is a conceptual view showing an individual identification method for the semiconductor chip 30 according to the present invention. In the present example, individual identification of the semiconductor chip 30 is performed from an appearance feature of a metal portion of the semiconductor chip 30. The metal portion may be a main electrode (surface electrode) provided on an upper surface of the semiconductor chip 30, may be a signal pad such as a gate pad, or may be a metal wiring. The main electrode is an electrode through which a main current flows in the semiconductor chip 30. The main current is, for example, a collector current or a drain current in a transistor, or an anode-cathode current in a diode. A weak signal after control of operation of the semiconductor chip 30 or measurement of operation of the semiconductor chip 30 flows through the signal pad. The weak signal is, for example, a control signal such as a base signal or a gate signal in a transistor, or a detection signal indicating a magnitude of the main current of the semiconductor chip 30, a temperature of the semiconductor chip 30, or the like. The metal wiring is a wiring connected to the main electrode or the signal pad, and for example, transmits a gate signal or the like.

The appearance feature of the metal portion may be, as an example, surface asperities of the metal portion, a distribution of a surface brightness of the metal portion, a surface shape of the metal portion, an appearance feature of a surface design of the metal portion, or a combination thereof. The surface design of the metal portion may be a linear design, and may include information of at least one of a line position, a line shape, a line branching position, or a line crossing position. The linear design may be a streak of the metal portion or a grain boundary pattern to be described later. The appearance feature of the present example is the grain boundary pattern which is an example of the surface design of the metal portion, but the grain boundary pattern may be read as another appearance feature unless the context otherwise requires specific matters regarding the grain boundary pattern. In general, an alloy material including Al or Cu is used as a material of a metal portion, such as a surface electrode, of a semiconductor device. Various alloy films are normally deposited by a sputtering method, and a grain boundary appears on a surface of the alloy film because growth of the alloy film deposited by the sputtering method is generally in an island mode. Since this grain boundary is randomly generated, a grain boundary design is a design unique to each semiconductor chip 30. Therefore, the individual semiconductor chip 30 can be identified. In the present specification, there is a case where the design formed by the grain boundary is referred to as a grain boundary pattern. In the present example, an image of an alloy film portion of each semiconductor chip 30 is acquired, and from the grain boundary pattern of that image, individual identification of the semiconductor chip 30 is performed. Note that as described above, individual identification of the semiconductor chip 30 may be performed by using the appearance feature of the metal portion, or may be performed by extracting the surface asperities or the brightness distribution other than the grain boundary pattern. Further, a wiring shape, a resulting appearance of an alignment mark, or the like may be used for individual identification.

The leftmost semiconductor chip 30 in the figure represents a semiconductor chip 30 in a fabrication process. As an example, a semiconductor chip 30 after an electrical characteristic test may be used. In the present example, images of two locations which are a main electrode 52 and a signal pad 42 are captured as the metal portion of the semiconductor chip 30.

Two schematic views located on a right hand side of the semiconductor chip 30 show the images of the metal portion. The upper image is a surface image of the main electrode 52, and the lower image is a surface image of the signal pad 42. A thick line and a black point in each image represent a grain boundary design, that is, a grain boundary pattern on a surface of the metal portion. As an example, a particle size of a crystal grain is 10 μm or more and 500 μm or less. In the present example, the two images are both color images.

Two schematic views located on a right hand side of the images show images obtained by performing image processing on each of the images. A data capacity of the image can be lowered by, for example, binarizing the image. Also, in the case of the present example, the grain boundary pattern is used as identification information, and therefore, the identification information is easily held even after binarization processing is performed. That is, the identification information and the binarization processing are compatible with each other, and therefore, the binarization processing is suitable. The binarized image and the above-described chip ID, electrical characteristic test result, or the like may be linked to each other. Note that the image processing is not limited to the binarization processing. For example, processing such as conversion into a grayscale, noise removal, or contrast enhancement may be performed.

The rightmost semiconductor chip 30 in the figure represents a semiconductor chip 30 after shipment. Also for the semiconductor chip 30 after shipment, an image of a same region as a region, from which the binarized image was acquired, on the semiconductor chip 30 after the test is acquired, and the grain boundary pattern is verified, and in this manner, it is possible to perform individual identification of the semiconductor chip 30.

According to the present example, individual identification can also be performed on the semiconductor chip 30 taken out from the tray, and therefore, the fabrication history can be traced over a wide range, and a device with a high reliability can be provided. In particular, there is a case where power semiconductor devices with a same surface layout have totally different characteristics due to a difference in drift layer specifications. According to the present example, defective characteristics of a final product due to mix-up of a model or a characteristic rank in a packaging process can be prevented. Also, a strategy of punching an identification number in a substrate or the like is not performed in the present method, and therefore, it is possible to trace the fabrication history without an increase in a fabrication process.

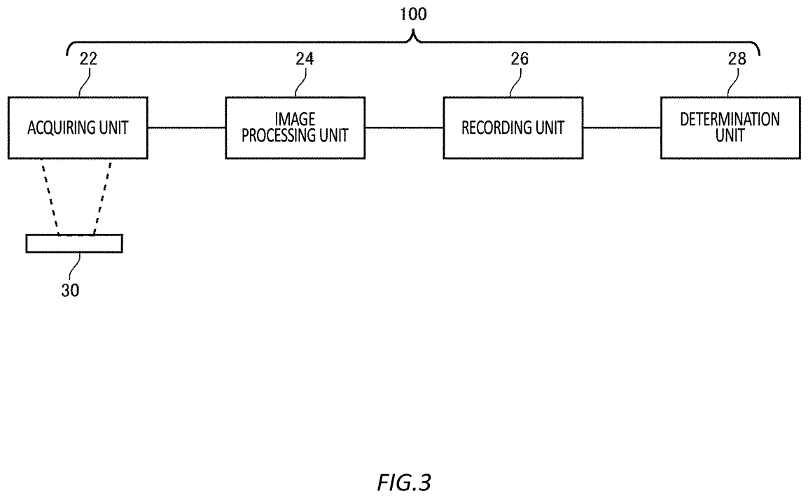

FIG. 3 is a diagram showing an example of a management apparatus 100 in an example of the present invention. The management apparatus 100 manages the semiconductor chip 30. The management apparatus 100 of the present example includes an acquiring unit 22, an image processing unit 24, and a recording unit 26.

The acquiring unit 22 acquires the image of the metal portion of the semiconductor chip 30. The acquiring unit 22 may acquire an image of a specified position of the metal portion of the semiconductor chip 30. The acquiring unit 22 may have an image capturing unit, and may acquire an image captured by an external camera. The acquiring unit 22 of the present example has an image capturing unit, and captures the image of the metal portion of the semiconductor chip 30. The acquiring unit 22 may be an image capturing apparatus having an alignment function, and may acquire an image captured by using the image capturing apparatus.

In FIG. 2 and figures subsequent thereto, an example where the acquiring unit 22 acquired an image captured by an image capturing apparatus including a bright-field type inspection mechanism will be described. Note that the acquiring unit 22 may acquire an image captured by another image capturing means such as a scanning electron microscope type inspection mechanism, a dark-field type inspection mechanism, or a confocal type inspection mechanism.

The image processing unit 24 extracts the appearance feature including the grain boundary pattern of the metal portion from the image acquired by the acquiring unit 22. The image processing unit 24 may extract the grain boundary pattern in the image by extracting a location at which pixel intensity or color tone is different compared to other regions. The image processing unit 24 may extract the grain boundary pattern by recognizing a pattern in the image by publicly-known machine learning or deep learning. The image processing unit 24 may extract a specific design such as a spiral or a loop as the grain boundary pattern. The image processing unit 24 may extract, as the grain boundary pattern, a line forming a closed path or a line not ended at a portion other than an end portion of the image in the image. The image processing unit 24 may perform the binarization processing. The image processing unit 24 may perform processing of binarizing the intensity of each pixel by comparing the intensity of each pixel of the color image with a preset threshold. The image processing unit 24 may extract the grain boundary pattern from the color image of FIG. 2, or may extract the grain boundary pattern from the binarized image.

The recording unit 26 records the grain boundary pattern as identification information of the semiconductor chip 30. The recording unit 26 may record the grain boundary pattern and the fabrication history of the semiconductor chip 30 in association with each other. A list of examples of the fabrication history include a lot No. of a wafer used, an ID of the wafer used, coordinates in the wafer used, date and time of fabrication, a fabrication location (line), a fabrication apparatus, date and time of inspection, an inspection result, an electrical property, and the like. That is, any information for specifying the fabrication process and characteristics of the semiconductor chip 30 may be included. The recording unit 26 may record the binarized image as the identification information. The recording unit 26 may record, as the identification information, the image of the grain boundary pattern extracted from the binarized image, or may generate a feature quantity which can be extracted from the grain boundary pattern, such as a position of an intersecting point of the grain boundary pattern, and record the feature quantity of the grain boundary pattern as the identification information.

The grain boundary pattern and the fabrication history are associated with each other, so that it is possible to trace the fabrication history. In this manner, for example, in a case where an abnormality is found in a product, a cause therefor can be easily found, and a period until the cause is found can be shortened. Therefore, it is possible to provide quick feedback to the fabrication process, which leads to improvement in a product quality.

The acquiring unit 22 may acquire an image of a semiconductor chip 30 targeted for identification. The semiconductor chip 30 targeted for identification is, for example, the semiconductor chip 30 after shipment in FIG. 2. The image processing unit 24 may extract the grain boundary pattern of the metal portion from the image of the semiconductor chip 30 targeted for identification. The management apparatus 100 may further include a determination unit 28. The determination unit 28 verifies the grain boundary pattern recorded in the recording unit 26 and the grain boundary pattern of the semiconductor chip 30 targeted for identification, and determines whether or not the grain boundary patterns match each other. Note that the acquiring unit 22 of the present example acquires the image of the semiconductor chip 30 in the form of the chip, but the acquiring unit 22 may acquire an image of a semiconductor chip 30 in the form of a wafer (before dicing).

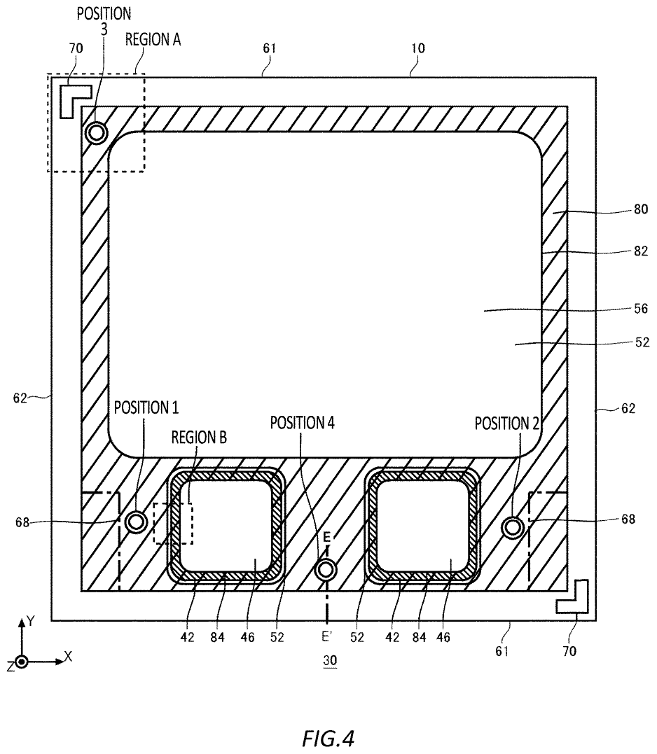

FIG. 4 is a view illustrating an image acquiring position of the semiconductor chip 30 in a top view. The semiconductor chip 30 has a semiconductor substrate 10, the main electrode 52, a plating 56, and a protective film 80. The semiconductor chip 30 may further include the signal pad 42, a plating 46, a gate runner 68, and a marker 70.

Inside the semiconductor substrate 10, a transistor or a diode may be provided. The transistor may be, for example, a MOSFET, or may be an IGBT. The diode may be a schottky barrier diode, or may be a PN junction diode. The semiconductor substrate 10 may be provided only with the transistor, may be provided only with the diode, or may be provided with both the transistor and the diode as in an RC-IGBT. Further, a device such as a memory or a logic IC may be provided. The semiconductor substrate 10 of the present example is provided with the MOSFET.

The semiconductor substrate 10 has a first end side 61 and a second end side 62 in the top view. The semiconductor substrate 10 of the present example has two first end sides 61 and two second end sides 62. The first end side 61 and the second end side 62 cross each other. The first end side 61 and the second end side 62 of the present example cross orthogonally to each other. The first end side 61 and the second end side 62 are end sides of the semiconductor chip 30. In FIG. 4, a direction parallel with the first end side 61 is an X axis, a direction parallel with the second end side 62 is a Y axis, and a direction orthogonal to the first end side 61 and the second end side 62 is a Z axis.

The main electrode 52 is provided above an upper surface of the semiconductor substrate 10. The main electrode 52 may be an electrode with a maximum area in the top view. The main electrode 52 may be an electrode through which a main current flows. The main electrode 52 may be an electrode provided above an active portion. The active portion may be a region where a channel is formed. The main electrode 52 of the present example is a source electrode. A large portion of the active portion is provided at a position overlapping with the plating 56. In a case where the semiconductor substrate 10 is provided with the diode, the main electrode 52 may be an anode electrode or a cathode electrode.

The protective film 80 is provided above the upper surface of the semiconductor substrate 10, and covers at least part of the metal portion. The main electrode 52 is an example of the metal portion described above. In a case where the semiconductor chip 30 has the signal pad 42, the signal pad 42 may also be an example of the metal portion. In FIG. 4, the protective film 80 is roughly hatched.

The protective film 80 is provided with a primary opening 82 through which the main electrode 52 is exposed. The primary opening 82 may be an opening with a maximum area. The primary opening 82 may be an opening with a maximum area where the main electrode 52 is exposed. In the primary opening 82, the plating 56 is provided above the main electrode 52.

The signal pad 42 is provided above the upper surface of the semiconductor substrate 10, and is separated from the main electrode 52. A plurality of signal pads 42 may be provided. In the present example, two signal pads 42 are provided. The signal pad 42 of the present example is provided between the primary opening 82 and the first end side 61 of the semiconductor chip 30 in the top view. Also, the signal pad 42 of the present example is disposed along the first end side 61.

The signal pad 42 may include any pad other than the main electrode 52. The signal pad 42 is, as an example, a gate pad, a sense pad, an anode pad for temperature sensing, a cathode pad for temperature sensing, or the like. In FIG. 4, the signal pad 42 is densely hatched. Note that in the top view, a portion overlapping with the plating 46 is not shown with the hatching.

The protective film 80 may be provided with an auxiliary opening 84 through which the signal pad 42 is exposed. The protective film 80 of the present example is provided with two auxiliary openings 84. The auxiliary opening 84 of the present example is also provided between the primary opening 82 and the first end side 61 of the semiconductor chip 30. An area of the auxiliary opening 84 is smaller than an area of the primary opening 82. In the auxiliary opening 84, the plating 46 is provided above the signal pad 42.

The main electrode 52 is provided over a wider range than the primary opening 82. The main electrode 52 of the present example is also provided between the signal pad 42 and the second end side 62 and between the signal pads 42 in the X axis direction. Provided between the signal pad 42 and the second end side 62 and between the signal pads 42 in the X axis direction may not be the active portion.

The main electrode 52 and the signal pad 42 are separated from each other at a position overlapping with the protective film 80. In FIG. 4, the position indicates an end portion of the main electrode 52 around the signal pad 42. The signal pad 42 of the present example is surrounded by the main electrode 52. The signal pad 42 may not be surrounded by the main electrode 52. The signal pad 42 may be provided between the main electrode 52 and the first end side 61. Note that for the sake of convenience, FIG. 4 does not show an outer peripheral end of the main electrode 52, but the outer peripheral end of the main electrode 52 may be slightly inside an outer peripheral end of the protective film 80.

The gate runner 68 is provided above the upper surface of the semiconductor substrate 10, and conveys a gate signal. The gate runner 68 is separated from the main electrode 52. The gate runner 68 may be provided at a position at least partially overlapping with the protective film 80. In FIG. 4, part of the gate runner 68 provided at the position overlapping with the protective film 80 is indicated by a dash-dotted line. The gate runner 68 and the signal pad 42 may at least partially overlap with each other in the X axis direction.

The marker 70 may be provided along the end side. The marker 70 may be provided outside any electrode and pad in the top view. In the present specification, the outside refers to a side closer to the end side of the semiconductor chip 30. The marker 70 of the present example is provided at a corner of the semiconductor chip 30. In the top view, the marker 70 may be provided between a corner of the semiconductor chip 30 and a corner of the main electrode 52. The marker 70 is used, for example, for discriminating an orientation of the semiconductor chip 30 upon package assembly.

The acquiring unit 22 may acquire the image of the metal portion covered with the protective film 80. When the assembly of the semiconductor chip 30 proceeds, the protective film 80, the plating 56, and the plating 46 are formed above the metal portion. Since a portion not covered with the protective film 80 is covered with the plating 56 or the plating 46, it is not possible to acquire the image of the metal portion. On the other hand, the image of the metal portion covered with the protective film 80 can be acquired even after the semiconductor chip 30 is packaged. Therefore, for example, even after shipment of the semiconductor chip 30, a package is disassembled with the protective film 80 left, so that the image of the metal portion covered with the protective film 80 can be acquired and it is possible to identify the semiconductor chip 30. In this manner, it is possible to perform quick failure analysis with a high accuracy upon occurrence of a trouble. Also, since the protective film 80 reduces a chronological change in the surface of the metal portion, the grain boundary pattern is less likely to change.

The protective film 80 may include a polyimide-based material as an example. The protective film 80 may be a semi-transparent polyimide-based organic protective film. The semi-transparent may be such a degree of transparency that the grain boundary pattern can be identified.

The metal portion may be the main electrode 52. The acquiring unit 22 may acquire the image of the main electrode 52 covered with the protective film 80. In a case where the semiconductor substrate 10 is provided with the diode, the acquiring unit 22 may acquire an image of the anode electrode covered with the protective film 80 as the main electrode 52. The metal portion may be the signal pad 42. The acquiring unit 22 may acquire an image of the signal pad 42 covered with the protective film 80. In a case where the semiconductor substrate 10 is provided with the diode, the signal pad 42 may not be provided. In that case, the metal portion may be the anode electrode or the cathode electrode.

As an indicator for deciding an image acquiring location on the upper surface of the semiconductor chip 30, Condition 1 to Condition 5 below can be used as a reference. Condition 1: a location where position alignment is easily performed. Condition 2: a location where a current density is low. Condition 3: a location where a temperature is less likely to increase. Condition 4: a location which is less likely to experience damage upon disassembly. Condition 5: a location where an image-capturing range can be secured.

Condition 1 is a point of view of position alignment upon verification. When there is a tag other than the grain boundary pattern in the image, position alignment for image-capturing and verification is easily performed and the accuracy is improved.

In terms of Condition 2, when the current density is low, migration is less likely to be generated, and the grain boundary pattern is less likely to change. As a result, the verification accuracy is improved. Also, in terms of Condition 3, for example, when the temperature is less likely to increase at a location where heat easily dissipates or the like, the grain boundary pattern is less likely to change. Condition 4 refers to a location where the grain boundary pattern is less likely to change or the image-capturing location is less likely to be broken, for example, due to the damage upon disassembly of the package. In terms of Condition 5, for example, in a case where an area of the metal portion included in the image is small and is comparable to a size of the crystal grain, the grain boundary pattern included in the image decreases in number, and it is difficult to perform verification on whether or not a same position is targeted. That is, a metal portion area of severalfold of the size of the crystal grain or more can be desirably secured.

The acquiring unit 22 may acquire the image of the main electrode 52 between the second end side 62 and the signal pad 42. A location indicated by Position 1 or Position 2 in the figure is an example of between the second end side 62 and the signal pad 42. At Position 1 or Position 2, an area larger than that between the primary opening 82 and the second end side 62 can be secured, for example (Condition 5). The acquiring unit 22 may acquire the image of the main electrode 52 within 1000 μm from the signal pad 42, and may include the signal pad 42 in the image. Since the image is acquired so as to include part of the signal pad 42, position alignment is easily performed with the signal pad 42 as the tag (Condition 1).

The acquiring unit 22 may acquire the image of the main electrode 52 between the gate runner 68 and the signal pad 42. The acquiring unit 22 may acquire the image of the main electrode 52 within 1000 μm from the gate runner 68, and may include the gate runner 68 in the image. In this case, position alignment is easily performed with the gate runner 68 as the tag (Condition 1). Note that the acquiring unit 22 may acquire the image of the main electrode 52 between another wiring such as a temperature sense wiring and the signal pad 42.

The acquiring unit 22 may acquire the image of the main electrode 52 between the marker 70 and the primary opening 82. The image may be an image including a portion of the main electrode 52 through which any of lines connecting the markers 70 and the primary opening 82 passes. Position 3 in the figure is an example of between the marker 70 and the primary opening 82. The acquiring unit 22 may acquire the image of the main electrode 52 within 1000 μm from the marker 70, and may acquire an image including the marker 70. In this manner, position alignment is easily performed with the marker 70 as the tag (Condition 1).

The acquiring unit 22 may acquire the image of the main electrode 52 at a position away from the active portion. A location indicated by Position 4 in the figure is an example of the position away from the active portion. Since the current density is low at the position away from the active portion, the grain boundary pattern is less likely to change (Condition 2). Also, since the position is close to the end side of the semiconductor chip 30, it is less likely to dissipate heat and increase the temperature (Condition 3).

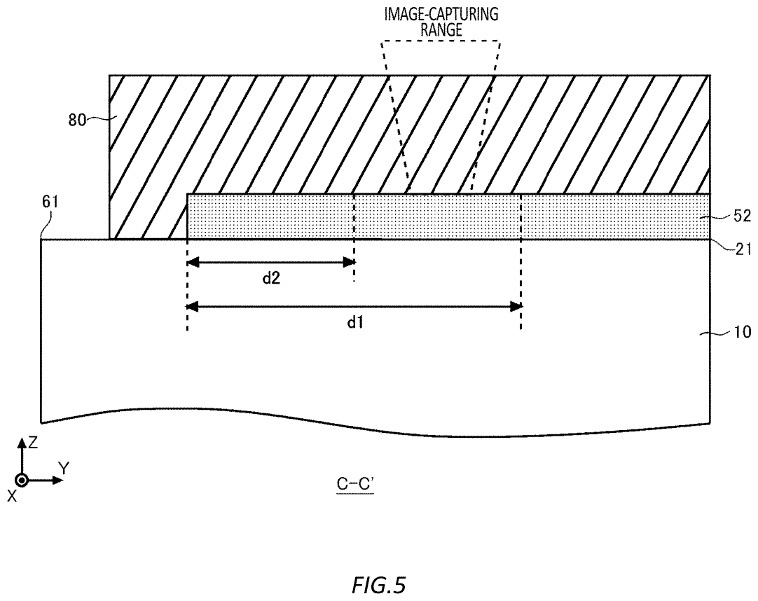

FIG. 5 is a view showing an example of an E-E′ cross section of FIG. 4. The E-E′ cross section is a YZ cross section traversing Position 4. In FIG. 5, the semiconductor chip 30 has the semiconductor substrate 10, the main electrode 52, and the protective film 80. In FIG. 5, illustration of a device structure inside the semiconductor substrate 10 and a lower surface side thereof is omitted.

The main electrode 52 and the protective film 80 are provided above an upper surface 21 of the semiconductor substrate 10. An end portion of the main electrode 52 is covered with the protective film 80. FIG. 5 shows distances d1 and d2 in the Y axis direction from an end portion of the main electrode 52 on a negative Y axis side. The distance d1 is an example of an upper limit of the image-capturing range, and the distance d2 is an example of a lower limit of the image-capturing range. The image-capturing range is an area of the main electrode 52 included in the image of the main electrode 52. The image-capturing range is, as an example, a rectangle with one side of 50 μm or more and 1000 μm or less.

The acquiring unit 22 may acquire an image of a region within 2000 μm from the end of the main electrode 52. That is, the distance d1 may be 2000 μm. The closer to the end of the main electrode 52, the lower the current density becomes (Condition 2). Also, since heat is easily dissipated, it is less likely to increase the temperature (Condition 3). The distance d1 may be 1000 μm, or may be 500 μm. At least part of the image-capturing range may be in a range of the distance d1 or less, or the entire image-capturing range may be in a range of the distance d1 or less.

The acquiring unit 22 may acquire an image at a position away from the end of the main electrode 52 by 100 μm or more. That is, the distance d2 may be 100 μm. Since the distance from the end of the main electrode 52 is secured, it is less likely to experience damage upon disassembly (Condition 4). Also, even in a case where disruption inspection is performed, the image-capturing range is less likely to be disrupted (Condition 4). The distance d2 may be 500 μm, or may be 1000 μm. At least part of the image-capturing range may be in a range of the distance d2 or more, or the entire image-capturing range may be in a range of the distance d2 or more.

FIG. 5 is the cross-sectional view between the signal pads 42 in FIG. 4, but the relationship described above may also be adopted to a case of image-capturing between the signal pad 42 and the second end side 62 in FIG. 4. That is, the image-capturing range at Position 1 or Position 2 in FIG. 4 may also satisfy the relationship of the distance d1 or the distance d2. The same also applies to the image-capturing range at Position 3.

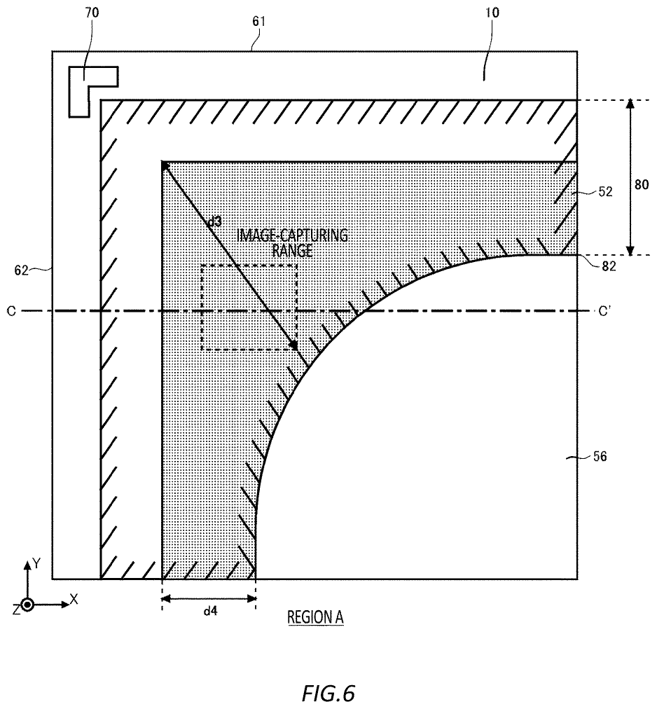

FIG. 6 is an enlarged view of a region A of FIG. 4. The region A is a region around a corner of the main electrode 52, which includes Position 3. In FIG. 6, the semiconductor chip 30 includes the plating 56, the main electrode 52, the protective film 80, and the semiconductor substrate 10.

A large portion of the main electrode 52 is covered with the plating 56 formed in the primary opening 82 of the protective film 80. Also, similar to FIG. 5, an end portion of the main electrode 52 is covered with the protective film 80. In FIG. 6, hatching is shown along an end portion of the protective film 80. Also, a portion of the main electrode 52 not covered with the plating 56 is lightly hatched.

In the primary opening 82 of the protective film 80, the plating 56 is provided above the main electrode 52. The upper surface 21 of the semiconductor substrate 10 is exposed outside the end portion of the main electrode 52. Note that part of the upper surface 21 of the semiconductor substrate 10 is covered with the protective film 80. The marker 70 is provided above the upper surface 21 of the semiconductor substrate 10 not covered with the protective film 80.

FIG. 6 shows an example of the image-capturing range at Position 3 by a dotted line. Also, a distance from the corner of the main electrode 52 to the image-capturing range is indicated by d3. The acquiring unit 22 may acquire an image of a region within 2000 μm from the corner of the main electrode 52. That is, the distance d3 may be 2000 μm or less. When close to the corner of the main electrode, position alignment is easily performed with the corner as the tag (Condition 1). The distance d3 may be 1000 μm or less.

Also, as an example, a width d4 of the main electrode 52 between the primary opening 82 and the first end side 61 or the second end side 62 is about 100 μm, and there is a case where a sufficient image-capturing range cannot be secured. Since a large image-capturing range can be obtained around the corner of the main electrode 52, verification is easily performed (Condition 5). The distance d3 may be 500 μm. At least part of the image-capturing range may be in a range of the distance d3 or less, or the entire image-capturing range may be in a range of the distance d3 or less.

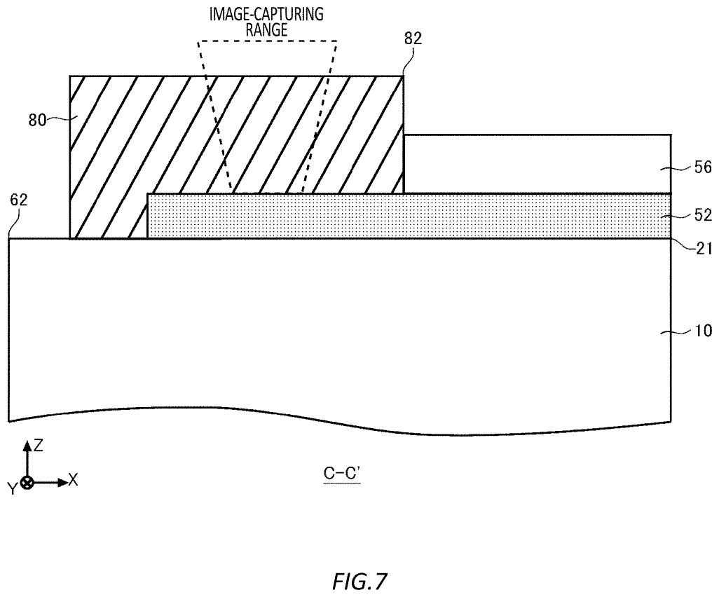

FIG. 7 is a view showing an example of a C-C′ cross section of FIG. 6. The C-C′ cross section is an XZ cross section traversing the image-capturing range at Position 3. In FIG. 7, the semiconductor chip 30 has the semiconductor substrate 10, the main electrode 52, the plating 56, and the protective film 80. In FIG. 7, illustration of a device structure inside the semiconductor substrate 10 and a lower surface side thereof is omitted.

In the C-C′ cross section, the plating 56 is formed up to an end portion of the primary opening 82. Since the plating 56 is opaque, a portion of the main electrode 52 overlapping with the protective film 80 outside the plating 56 is selected as the image-capturing range.

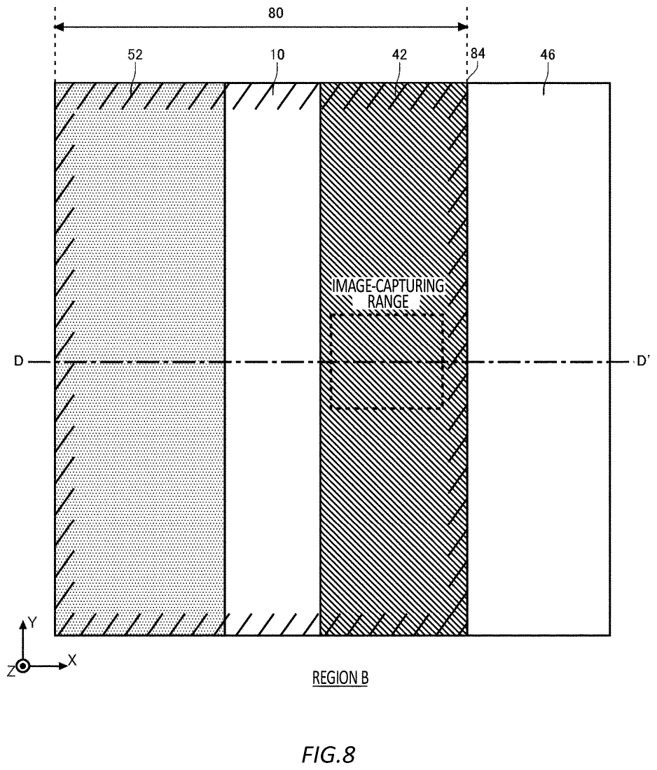

FIG. 8 is an enlarged view of a region B of FIG. 4. The region B is a region around the signal pad 42. In FIG. 8, the semiconductor chip 30 includes the plating 46, the signal pad 42, the protective film 80, the semiconductor substrate 10, and the main electrode 52.

A large portion of the signal pad 42 is covered with the plating 46 formed in the auxiliary opening 84 of the protective film 80. Also, an end portion of the signal pad 42 is covered with the protective film 80. In FIG. 8, hatching is shown along an end portion of the protective film 80. Also, a portion of the signal pad 42 not covered with the plating 46 is densely hatched.

The signal pad 42 is separated from the main electrode 52. The upper surface 21 of the semiconductor substrate 10 is exposed between the signal pad 42 and the main electrode 52. The protective film 80 covers part of the signal pad 42, the upper surface 21 of the semiconductor substrate 10, and the main electrode 52. In FIG. 8, the main electrode 52 is lightly hatched.

The acquiring unit 22 may acquire the image of the signal pad 42. A current flowing through the signal pad 42 is smaller than that of the main electrode 52 (Condition 2). Also, since the signal pad 42 is separated from the main electrode 52, it is less likely to carry the temperature from the main electrode 52 (Condition 3). Therefore, the grain boundary pattern is less likely to change. FIG. 8 shows an example of the image-capturing range of the signal pad 42. The acquiring unit 22 may acquire only an image of the signal pad 42, or may acquire an image partially including the signal pad 42.

The signal pad 42 may be a gate pad. The signal pad 42 may be an anode pad or a cathode pad for temperature sensing, may be a pad for current sensing, or may be a pad for screening. Since any pad is separated from the main electrode 52, the grain boundary pattern is less likely to change.

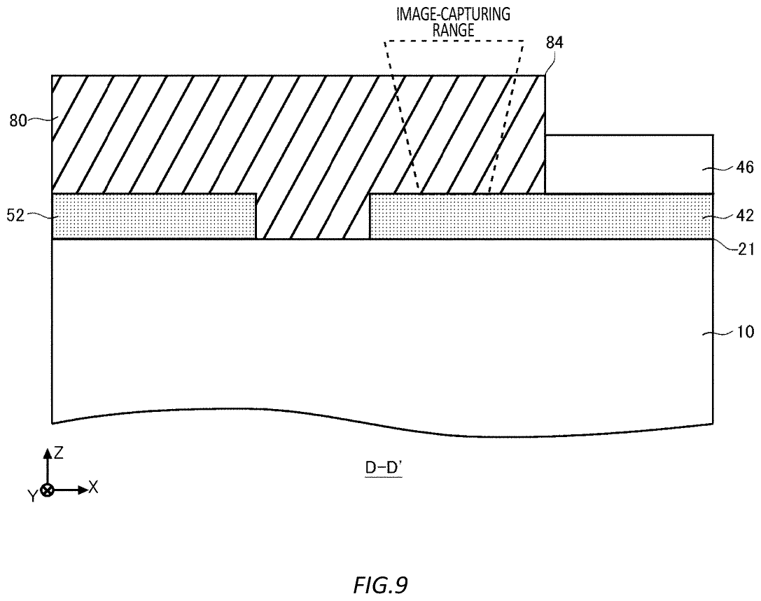

FIG. 9 is a view showing an example of a D-D′ cross section of FIG. 8. The D-D′ cross section is an XZ cross section traversing the image-capturing range of FIG. 8. In FIG. 9, the semiconductor chip 30 has the semiconductor substrate 10, the signal pad 42, the main electrode 52, the plating 46, and the protective film 80. In FIG. 9, illustration of a device structure inside the semiconductor substrate 10 and a lower surface side thereof is omitted.

In the D-D′ cross section, the plating 46 is formed up to an end portion of the auxiliary opening 84. Since the plating 46 is opaque, a portion of the signal pad 42 not overlapping with the plating 46 and overlapping with the protective film 80 is selected as the image-capturing range.

The acquiring unit 22 may acquire images of the metal portion covered with the protective film 80 at a plurality of positions. For example, since there is a risk of a change in a particle size pattern due to a temperature increase or of breakage upon disassembly, the images of the plurality of locations are acquired so that a probability of verification being able to be performed increases. In particular, the image of the metal portion may be acquired according to different conditions of Condition 1 to Condition 5 described above. For example, images at both any of Position 1 at which position alignment is easily performed to Position 3 and Position 4 at which the current density is low may be acquired. In this manner, the probability of verification being able to be performed further increases. The acquiring unit 22 may acquire images of three or more locations, or may acquire images of four or more locations.

The acquiring unit 22 may acquire images of both the main electrode 52 covered with the protective film 80 and the signal pad 42 covered with the protective film 80. Also in this manner, the probability of verification being able to be performed further increases.

An area of the main electrode 52 included in the image of the main electrode 52 may be larger than an area of the signal pad 42 included in the image of the signal pad 42. With the larger area, verification is easily performed (Condition 5). Since the area of the main electrode 52 is large, the main electrode 52 can be photographed over a wide range. Note that in the description of FIGS. 4 to 9, the semiconductor chip 30 is provided with the plating 56 and the plating 46, but the semiconductor chip 30 may be assembled by wire bonding or the like with no plating. Also in that case, the acquiring unit 22 may acquire the images of the positions described in FIGS. 4 to 9. In this manner, effects similar to those of FIGS. 4 to 9 can be obtained.

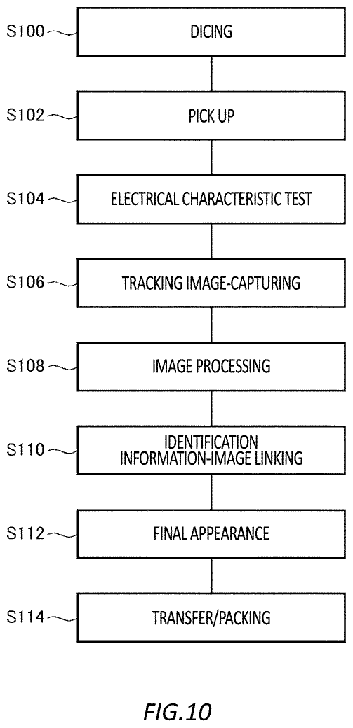

FIG. 10 is a chart showing an example of a fabrication flow of the semiconductor chip 30 to which the management method of the present invention was adopted. The fabrication flow of the present example includes a dicing process S100, a pickup process S102, an electrical characteristic test process S104, a tracking image-capturing process S106, an image processing process S108, an identification information-image linking process S110, a final appearance process S112, and a transfer/packing process S114. In the tracking image-capturing process S106, the image processing process S108, and the identification information-image linking process S110, the process described in FIGS. 1 to 9 may be performed.

In the dicing process S100, a wafer is diced, and is cut into individual semiconductor chips 30. A main electrode 52 and a signal pad 42 as a metal portion are formed before the dicing process S100. In the pickup process S102, the individual semiconductor chip 30 is taken out, and in the electrical characteristic test process S104, an electrical characteristic test is performed for the semiconductor chip 30. The semiconductor chip 30 determined as having favorable electrical properties proceeds to a next process.

In the tracking image-capturing process S106, an image of the metal portion is acquired. In the image processing process S108, a grain boundary pattern of the metal portion is extracted from the image acquired in the tracking image-capturing process S106. In the image processing process S108, binarization processing may be performed.

In the identification information-image linking process S110, the grain boundary pattern is recorded as identification information on the semiconductor chip 30. The grain boundary pattern may be associated with the fabrication history described above. Also, the image or the binarized image acquired in the tracking image-capturing process S106 may be saved.

In the final appearance process S112, appearance inspection is performed. The appearance inspection is inspection for visually checking a surface condition of the semiconductor chip 30 in a wafer process or after dicing to detect a defect, a scratch, an abnormality, or the like in order to secure reliability of a semiconductor device. In the transfer/packing process S114, the semiconductor chip 30 having passed the appearance inspection is transferred/packed in a shipment tray and is shipped.

Acquisition of the image in the tracking image-capturing process S106 may be performed upon the appearance inspection for the semiconductor chip 30. As an example of the appearance inspection, an automatic appearance inspection apparatus with a combination of a camera and image processing is used to photograph a surface image of the semiconductor chip 30, analyze the image, and automatically detect a defect or the like. The defect has a size of several tens of μm as an example, and is close in size to the size of a crystal grain. Therefore, the image acquired upon the appearance inspection may be acquired as an image from which the grain boundary pattern is extracted. Alternatively, upon the appearance inspection, an image from which the grain boundary pattern is extracted may be additionally photographed. In this manner, the image can be acquired without an increase in a number of fabrication processes and complication. The image may be photographed by an automatic appearance inspection apparatus having an alignment function.

The tracking image-capturing process S106 to the final appearance process S112 may be all automatically performed by the automatic appearance inspection apparatus. Note that the fabrication flow shown in FIG. 10 shows part of the fabrication flow for the semiconductor chip 30. Also, a semiconductor chip 30 in the form of a wafer after surface electrode wiring formation may be targeted for image-capturing. In that case, before the dicing process S100, the tracking image-capturing process S106 may be performed, or the tracking image-capturing process S106 to the identification information-image linking process S110 may be performed. In that case, acquisition of the image in the tracking image-capturing process S106 may be performed upon appearance inspection in the form of the wafer before dicing.

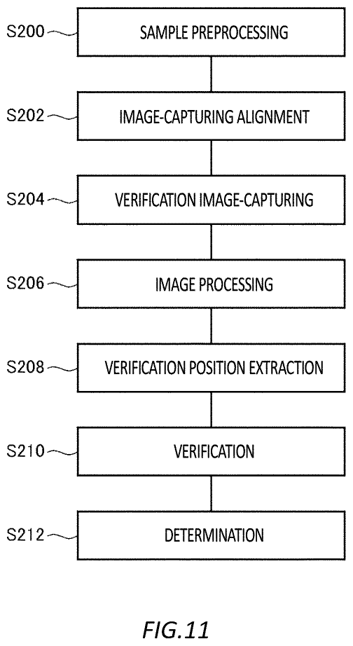

FIG. 11 is a chart showing an example of a verification flow for the semiconductor chip 30. In the verification flow, for example, individual identification of a semiconductor chip 30 after shipment is performed. The verification flow of the present example includes a sample preprocessing process S200, an image-capturing alignment process S202, a verification image-capturing process S204, an image processing process S206, a verification position extraction process S208, a verification process S210, and a determination process S212.

In the sample preprocessing process S200, a package is disassembled, and a semiconductor chip 30 is taken out. At this time, since there is a risk of breakage, there is Condition 4 as the indicator described above. In the image-capturing alignment process S202, an image-capturing position in a metal portion of the semiconductor chip 30 is adjusted. At this time, when the tag according to Condition 1 or the image-capturing range of the sufficient size according to Condition 5 as described above can be secured, position alignment and verification are easily performed.

When alignment is completed, an image of the metal portion is captured in the verification image-capturing process S204. At a same position as the image-capturing position in the tracking image-capturing process S106, image-capturing is performed herein under an equivalent condition. In the image processing process S206, image processing is performed on the captured image. In the image processing process S206, binarization processing may be performed.

In the verification position extraction process S208, a range used for verification or a particular grain boundary pattern used for verification in the image is extracted. In the verification process S210, the grain boundary pattern recorded as the identification information in the identification information-image linking process S110 of FIG. 5 and the grain boundary pattern extracted in the verification position extraction process S208 are verified against each other. In particular, verification may be performed based on a specific pattern of the metal portion, such as a spiral or a loop. Also, with shipment information on the semiconductor chip 30, a verification accuracy can be improved and a verification time can be shortened by narrowing down verification targets based on that data.

In the determination process S212, it is determined whether or not the two grain boundary patterns match each other, and individual identification is performed. At this time, since erroneous detection increases when the grain boundary pattern changes, there are Condition 2 and Condition 3 as the indicators described above. Note that image-capturing in the verification flow may also be performed by an automatic appearance inspection apparatus having an alignment function.

While the embodiments of the present invention have been described, the technical scope of the present invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

The present specification and the drawings also disclose an invention according to each of the following claims.
[Item 1] A semiconductor chip management method comprising:
   acquiring an image of a metal portion of a semiconductor chip;
   extracting a grain boundary pattern of the metal portion from the image; and
   recording the grain boundary pattern as identification information on the semiconductor chip.
[Item 2] The semiconductor chip management method according to item 1, wherein
   the acquiring the image is performed upon appearance inspection of the semiconductor chip.
[Item 3] A semiconductor chip fabrication method comprising:
   forming a metal portion on a semiconductor chip;
   acquiring an image of the metal portion of the semiconductor chip;
   extracting a grain boundary pattern of the metal portion from the image; and
   recording the grain boundary pattern as identification information on the semiconductor chip.
[Item 4] The semiconductor chip fabrication method according to item 3, wherein
   the acquiring the image is performed upon appearance inspection of the semiconductor chip.

What is claimed is:

1. A semiconductor chip management apparatus comprising:
an acquiring unit which acquires an image of a metal portion of a semiconductor chip;
an image processing unit which extracts an appearance feature of the metal portion from the image; and
a recording unit which records the appearance feature as identification information of the semiconductor chip.

2. The semiconductor chip management apparatus according to claim 1, wherein
the recording unit records the appearance feature and a fabrication history of the semiconductor chip in association with each other.

3. The semiconductor chip management apparatus according to claim 1, wherein
the semiconductor chip has:
a semiconductor substrate; and
a protective film provided above an upper surface of the semiconductor substrate and covering at least part of the metal portion, and
the acquiring unit acquires the image of the metal portion covered with the protective film.

4. The semiconductor chip management apparatus according to claim 3, wherein
the protective film includes a polyimide-based material.

5. The semiconductor chip management apparatus according to claim 3, wherein
the metal portion is a main electrode provided above the upper surface of the semiconductor substrate.

6. The semiconductor chip management apparatus according to claim 5, wherein
the protective film is provided with a primary opening through which the main electrode is exposed,
the semiconductor chip has a signal pad separated from the main electrode and provided between the primary opening and a first end side of the semiconductor chip in a top view, and
the acquiring unit acquires an image of the main electrode between a second end side crossing the first end side and the signal pad.

7. The semiconductor chip management apparatus according to claim 6, wherein
the semiconductor chip has a gate runner provided above the upper surface of the semiconductor substrate and conveying a gate signal, and
the acquiring unit acquires an image of the main electrode between the gate runner and the signal pad.

8. The semiconductor chip management apparatus according to claim 5, wherein
the semiconductor chip has a marker provided along an end side,
the protective film is provided in a primary opening through which the main electrode is exposed, and
the acquiring unit acquires an image of the main electrode between the marker and the primary opening.

9. The semiconductor chip management apparatus according to claim 5, wherein
the acquiring unit acquires an image of a region within 2000 μm from an end of the main electrode.

10. The semiconductor chip management apparatus according to claim 5, wherein
the acquiring unit acquires an image of a position away from an end of the main electrode by 100 μm or more.

11. The semiconductor chip management apparatus according to claim 5, wherein
the acquiring unit acquires an image of a region within 2000 μm from a corner of the main electrode.

12. The semiconductor chip management apparatus according to claim 3, wherein
the semiconductor chip has:
a main electrode provided above the upper surface of the semiconductor substrate; and
a signal pad provided above the upper surface of the semiconductor substrate and separated from the main electrode, and
the metal portion is the signal pad.

13. The semiconductor chip management apparatus according to claim 12, wherein
the signal pad is a gate pad.

14. The semiconductor chip management apparatus according to claim 3, wherein
the acquiring unit acquires images of the metal portion covered with the protective film at a plurality of positions.

15. The semiconductor chip management apparatus according to claim 14, wherein
the semiconductor chip has:
a main electrode provided above the upper surface of the semiconductor substrate; and
a signal pad provided above the upper surface of the semiconductor substrate and separated from the main electrode,
the metal portion includes the main electrode and the signal pad, and
the acquiring unit acquires an image of both the main electrode covered with the protective film and the signal pad covered with the protective film.

16. The semiconductor chip management apparatus according to claim 15, wherein
an area of the main electrode included in the image of the main electrode is larger than an area of the signal pad included in the image of the signal pad.

17. The semiconductor chip management apparatus according to claim 5, wherein
the semiconductor substrate is provided with a diode, and
the main electrode is an anode electrode of the diode.

18. The semiconductor chip management apparatus according to claim 1, wherein
the appearance feature is a grain boundary pattern of the metal portion.

19. The semiconductor chip management apparatus according to claim 18, wherein
the image processing unit binarizes the image, and
the recording unit records the image binarized.

20. The semiconductor chip management apparatus according to claim 2, wherein
the appearance feature is a grain boundary pattern of the metal portion.
